(19) United States
(12) Patent Application Publication
(10) Pub. No.: US 2025/0374476 A1
(43) Pub. Date: Dec. 4, 2025

(54) ELECTRONIC APPARATUS AND COOLING MODULE

(71) Applicant: Lenovo (Singapore) Pte. Ltd., Singapore (SG)

(72) Inventors: Ryota Watanabe, Kanagawa (JP); Junki Hashiba, Kanagawa (JP); Yudai Tsurumi, Kanagawa (JP); Takanori Hoshino, Kanagawa (JP)

(73) Assignee: Lenovo (Singapore) Pte. Ltd., Singapore (SG)

(21) Appl. No.: 19/210,447

(22) Filed: May 16, 2025

(30) Foreign Application Priority Data
May 29, 2024 (JP) 2024-086912

(51) Int. Cl. H05K 7/20; G06F 1/20

(52) U.S. Cl. CPC H05K 7/20145; G06F 1/203; H05K 7/2039

(57) ABSTRACT

An electronic apparatus includes a chassis including a first ventilation port, a second ventilation port, and a third ventilation port located between the first ventilation port and the second ventilation port, a heating element mounted in the chassis, and a cooling module mounted in the chassis and configured to cool the heating element. The cooling module includes a pair of heat sinks, a heat transport device, a pair of fans each having a first outlet capable of discharging air toward the heat sink, one of the fans being disposed to face the one heat sink and the other fan being disposed to face the other heat sink, and a metal plate disposed between the pair of fans such that one edge portion faces the third ventilation port and capable of diffusing heat from the heating element.

### BACKGROUND OF THE INVENTION

### CROSS-REFERENCE TO RELATED APPLICATIONS

This application claims priority to Japanese Patent Application No. 2024-086912 filed on May 29, 2024, the contents of which are hereby incorporated herein by reference in their entirety.

### TECHNICAL FIELD

The present invention relates to an electronic apparatus and a cooling module.

### BACKGROUND

An electronic apparatus such as a laptop PC is equipped with a heating element such as a CPU. Such an electronic apparatus is often equipped with a cooling module including a fan or a heat sink. The cooling module is capable of absorbing heat generated by the heating element and radiating the heat to an outside (see, for example, Japanese Patent No. 7371170).

In the configuration of Japanese Patent No. 7371170, left and right fans each include a pair of outlets, and are capable of discharging air in two directions. The air leaving one of the outlets passes through a heat sink immediately downstream of the outlet and is then discharged to an outside of a chassis. The air leaving the other outlet flows along a surface of a substrate disposed between the left and right fans and is then discharged to the outside of the chassis while cooling mounted components.

Incidentally, there is a strong demand for miniaturization of a chassis in the electronic apparatus as described above. Therefore, a space of the cooling module and a peripheral portion thereof is narrow, and ventilation resistance of air discharged from the fan is likely to increase. For example, in the configuration of Japanese Patent No. 7371170, a substrate and a vapor chamber extend close to an exhaust port provided on a rear side surface of the chassis. These components create ventilation resistance of air flowing from the fan to the exhaust port. Therefore, even in such a configuration, it is required to reduce the ventilation resistance of the air discharged from the fan to increase an air volume of the fan and to improve cooling performance of the cooling module.

### SUMMARY

Embodiments of the present disclosure include an electronic apparatus and a cooling module capable of reducing ventilation resistance of air discharged from a fan and improving cooling capacity.

An electronic apparatus according to a first aspect of the present invention includes a chassis including a first ventilation port, a second ventilation port, and a third ventilation port located between the first ventilation port and the second ventilation port, a heating element mounted in the chassis, and a cooling module mounted in the chassis and configured to cool the heating element, in which the cooling module includes a pair of heat sinks, one of the heat sinks being disposed to face the first ventilation port and the other being disposed to face the second ventilation port, a heat transport device configured to transport heat from the heating element to the heat sink, a pair of fans each having a first outlet capable of discharging air toward the heat sink, one of the fans being disposed to face the one heat sink and the other being disposed to face the other heat sink, and a metal plate disposed between the pair of fans such that one edge portion faces the third ventilation port and capable of diffusing the heat from the heating element, and the metal plate includes a plurality of fins standing upright from a surface of the metal plate and arranged along the one edge portion, and a hole part penetrating the metal plate in a plate thickness direction.

A cooling module according to a second aspect of the present invention is a cooling module that is mounted in an electronic apparatus, the cooling module including a pair of heat sinks, a heat transport device connected to the heat sinks, a pair of fans each having a first outlet capable of discharging air toward the heat sink, one of the fans being disposed to face one of the heat sinks and the other being disposed to face the other of the heat sinks, and a metal plate disposed between the pair of fans, in which the metal plate includes a plurality of fins standing upright a surface of the metal plate and arranged along one edge portion of the metal plate, and a hole part penetrating the metal plate in a plate thickness direction.

One or more embodiments of the present invention reduce ventilation resistance of air discharged from a fan and improve cooling capacity.

### BRIEF DESCRIPTION OF THE DRAWINGS

FIG. 1 is a schematic plan view of an electronic apparatus according to an embodiment as viewed from above.

FIG. 2 is a plan view schematically illustrating an internal structure of a chassis in accordance with one or more embodiments.

FIG. 3 is a perspective view of a rear portion of the electronic apparatus as viewed from a bottom surface side in accordance with one or more embodiments.

FIG. 4 is a schematic perspective view of a metal plate in accordance with one or more embodiments.

FIG. 5 is a schematic cross-sectional side view of a rear edge portion of the chassis and a peripheral portion thereof in accordance with one or more embodiments.

FIG. 6 is a schematic cross-sectional rear view of the rear edge portion of the chassis and the peripheral portion thereof in accordance with one or more embodiments.

### DETAILED DESCRIPTION

Hereinafter, embodiments of an electronic apparatus and a cooling module according to the present invention will be described in detail with reference to example embodiments and the accompanying drawings.

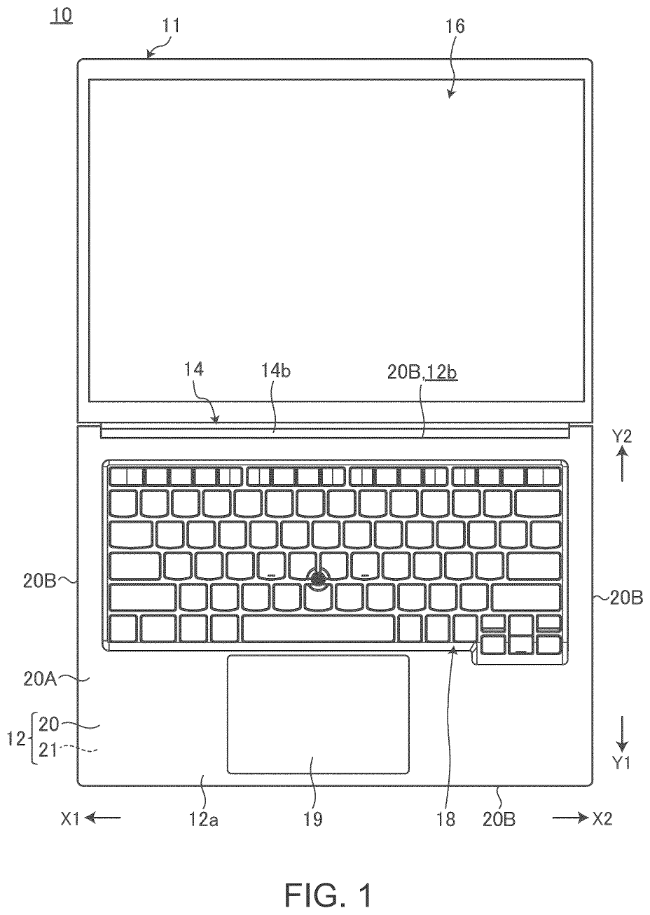

FIG. 1 is a schematic plan view of an electronic apparatus 10 according to one or more embodiments as viewed from above. As illustrated in FIG. 1, the electronic apparatus 10 of one or more embodiments is a clamshell-type laptop PC. The electronic apparatus 10 has a configuration in which a cover 11 and a chassis 12 are connected to each other by a hinge 14 so as to be relatively rotatable. In one or more embodiments, the electronic apparatus 10 of the laptop PC is exemplified, but the electronic apparatus may be other than the laptop PC, such as a tablet PC, a smartphone, or a portable game machine.

The cover 11 is a thin flat box-shaped chassis. The cover 11 is provided with a display 16. The display 16 is, for example, an organic EL display or a liquid crystal display.

The chassis 12 is a thin flat box body. A keyboard device 18 and a touch pad 19 are provided on a top surface (surface 12a) of the chassis 12. Hereinafter, the chassis 12 and each component mounted in the chassis 12 will be described based on a posture of an operator operating the keyboard device 18, in which a width direction (left and right) of the chassis 12 will be referred to as X1 and X2 directions, a depth direction (front and rear) of the chassis 12 will be referred to as Y1 and Y2 directions, and a thickness direction (top and bottom) of the chassis 12 will be referred to as Z1 and 22 directions. The X1 and X2 directions may be collectively referred to as an X direction, and the Y1 and Y2 directions and the Z1 and Z2 directions may be similarly referred to as a Y direction and a Z direction. Each of these directions is a direction determined for convenience of description, and may be changed depending on a usage state, an installation posture, or the like of the electronic apparatus 10.

The chassis 12 includes a chassis member 20 that forms a top surface and four peripheral side surfaces, and a cover material 21 that forms a bottom surface. The chassis member 20 is configured by forming standing walls 20B on four peripheral edges of a cover plate 20A that forms the surface 12a of the chassis 12. Therefore, the chassis member 20 has a substantially bathtub shape with an open bottom surface. The cover material 21 has a substantially flat plate shape and serves as a cover that closes a bottom surface opening of the chassis member 20. The chassis member 20 and the cover material 21 overlap in the thickness direction and are connected to each other in an attachable and detachable manner. The standing walls 20B may be formed on the cover material 21. In this case, the chassis member 20 may be configured of only the cover plate 20A.

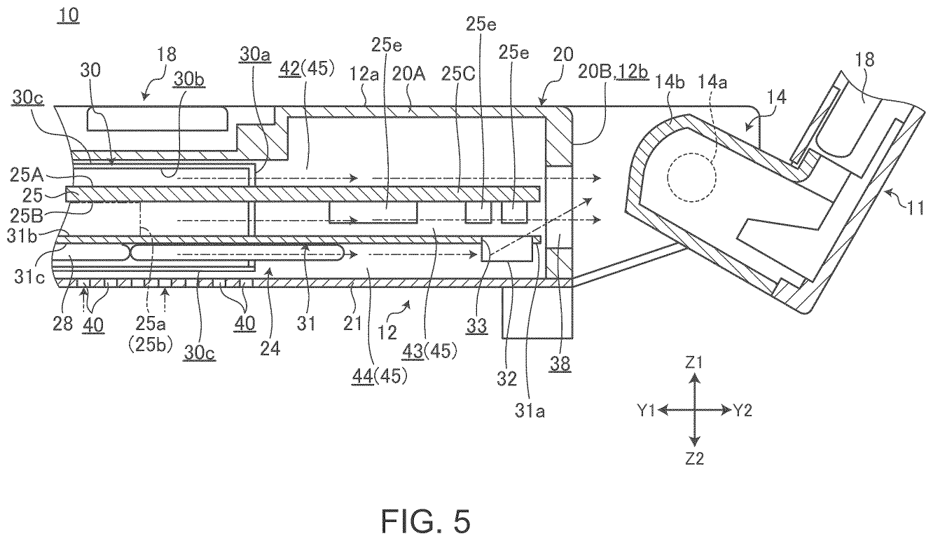

The hinge 14 is installed in a recessed hinge disposition groove 12b formed in a rear edge portion of the chassis 12 and connects the chassis 12 and the cover 11 to each other. The hinge 14 has a structure in which, for example, a hinge shaft 14a serving as a rotation axis is supported at both end parts of a hinge chassis 14b in a longitudinal direction (see FIG. 5). The hinge 14 of one or more embodiments is configured in a so-called one-bar shape in which the hinge chassis 14b extends along the longitudinal direction of the hinge disposition groove 12b. The hinge 14 descends obliquely backward while the hinge chassis 14b rotates integrally with the cover 11 (see FIG. 5). The hinge 14 has a structure that secures a rotation angle of the cover 11 in this manner, that is, a so-called drop-down structure. The hinge 14 may have a structure other than the above structure.

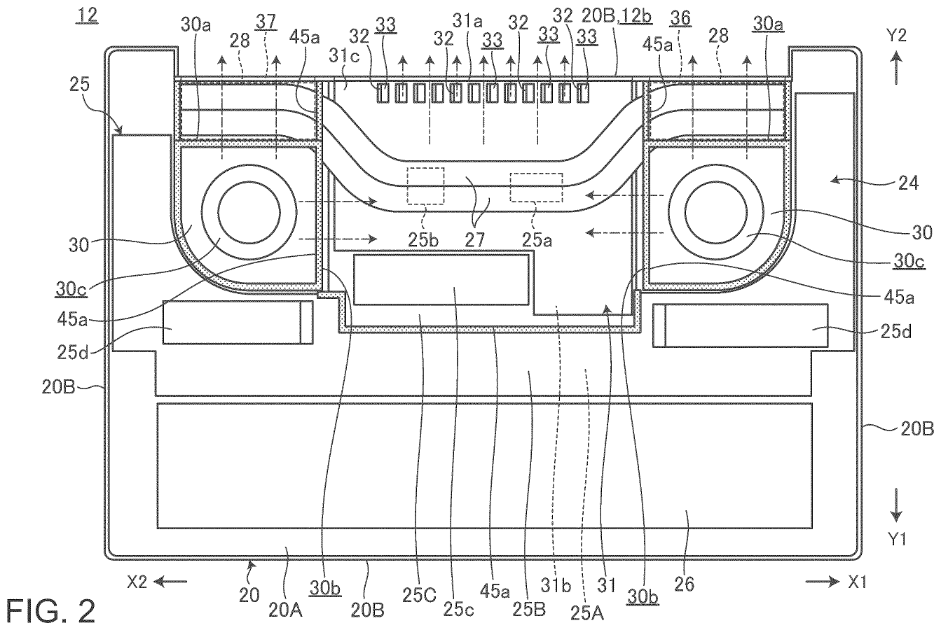

FIG. 2 is a plan view schematically illustrating an internal structure of the chassis 12. FIG. 2 is a view of an inside of the chassis member 20 as viewed from a bottom surface side with the cover material 21 removed.

As illustrated in FIG. 2, a cooling module 24, a motherboard 25, and a battery device 26 are accommodated inside the chassis 12. Various electronic components, mechanical components, and the like can be accommodated inside the chassis 12.

The motherboard (substrate) 25 is a circuit board that serves as a main board of the electronic apparatus 10. The motherboard 25 is disposed close to the Y2 side of the chassis 12 and extends in the X direction. The battery device 26 is a rechargeable battery that serves as a power source of the electronic apparatus 10. The battery device 26 is disposed close to the Y1 side of the motherboard 25 and extends in the X direction.

The motherboard 25 of one or more embodiments mounts a central processing unit (CPU) 25a and a graphics processing unit (GPU) 25b. The CPU 25a is a processing device that performs computations related to primary control or processing of the electronic apparatus 10. The GPU 25b is a processing device that performs computations necessary for image rendering, such as 3D graphics. Power supply components and memories for the CPU 25a and the GPU 25b are mounted on the periphery of the CPU 25a and the GPU 25b. Various electronic components such as a memory module 25c, a storage device 25d, and a communication module are mounted on the motherboard 25. The memory module 25c is, for example, a compression attached memory module (CAMM) or a dual inline memory module (DIMM). The storage device 25d is, for example, a solid state drive (SSD).

For example, the motherboard 25 has a top surface (first surface 25A) that serves as an attachment surface with respect to the chassis member 20, and a bottom surface (second surface 25B) that serves as a mounting surface for the CPU 25a and the like.

The CPU 25a and the GPU 25b are heating elements having the largest calorific value among electronic components accommodated in the chassis 12. The cooling module 24 is capable of absorbing and diffusing heat generated by the CPU 25a and the GPU 25b and discharging the heat to an outside of the chassis 12. The cooling module 24 of one or more embodiments is also capable of cooling the memory module 25c and the like.

As illustrated in FIG. 2, the cooling module 24 of one or more embodiments includes a set of two heat pipes 27, a pair of heat sinks 28 and 28, a pair of fans 30 and 30, and a metal plate 31.

The heat pipe 27 is a pipe-shaped heat transport device. The heat pipe 27 has a configuration in which a metal pipe is thinly and flatly crushed and is formed to have an elliptical-shaped cross section and a working fluid is enclosed in a sealed space formed therein. Examples of the working fluid include water, alternative fluorocarbons, acetone, butane, and the like. The heat pipes 27 can be used in a set of two, for example. The heat pipe 27 partially overlaps the CPU 25a and the GPU 25b in the Z direction and is connected to the CPU 25a and the GPU 25b. Both end parts of the heat pipe 27 are connected to the left and right heat sinks 28, respectively. As a result, the heat pipe 27 efficiently transports the heat generated by the CPU 25a and the GPU 25b to the left and right heat sinks 28.

The heat pipe 27 is thermally connected to the CPU 25a and the GPU 25b, for example, in the vicinity of the center in the longitudinal direction. The metal plate 31 is interposed between the heat pipe 27 and the CPU 25a and the GPU 25b (see also FIG. 5).

The metal plate 31 is a thin plate formed of a metal having a high thermal conductivity, such as copper or aluminum. The metal plate 31 of one or more embodiments is a copper plate. The metal plate 31 functions as a heat spreader that absorbs and diffuses the heat from the CPU 25a and the GPU 25b. The metal plate 31 also functions as a heat transfer member that transfers the heat from the CPU 25a and the GPU 25b to the heat pipe 27.

The metal plate 31 extends in a substantially rectangular shape so as to fill a space between the left and right fans 30 and 30 and a space between the left and right heat sinks 28 and 28 in a plan view illustrated in FIG. 2. The metal plate 31 covers a part (portion 25C) of the motherboard 25 disposed between the left and right fans 30 and 30 and the CPU 25a and the like mounted on the portion 25C from the second surface 25B side (Z2 side) (see also FIG. 5). An edge portion (one edge portion 31a) of the metal plate 31 on the Y2 side is disposed to face an inner wall surface of a portion of the standing wall 20B on the Y2 side that corresponds to the hinge disposition groove 12b. Hereinafter, a portion of the standing wall 20B that corresponds to the hinge disposition groove 12b may be referred to as an “outer wall 20B”. The one edge portion 31a of the metal plate 31 is disposed with a slight gap with the inner wall surface of the outer wall 20B (see FIG. 5). A plurality of fins 32 and a plurality of hole parts 33 are arranged in parallel on the one edge portion 31a of the metal plate 31. Specific configurations of the fins 32 and the hole parts 33 will be described below.

The heat sinks 28 are provided at positions close to edge portions of the chassis 12 on the X1 and X2 sides. One of the heat sinks 28 is disposed to face a side surface (first outlet 30a) on the Y2 side of one of the fans 30. The other of the heat sinks 28 is disposed to face a side surface (first outlet 30a) on the Y2 side of the other of the fans 30. The heat sink 28 is formed of a metal having a high thermal conductivity, such as aluminum or copper. The heat sink 28 has a structure in which a plurality of fins formed of thin metal plates is arranged at regular intervals in the X direction. Each fin stands upright in the Z direction and extends in the Y direction. Top and bottom end surfaces (Z direction end surfaces) of each fin are integrally supported by thin plate-shaped portions. A gap, through which air sent from the fans 30 passes, is formed between the fins adjacent to each other. As a result, air sent from the first outlet 30a of each fan 30 is capable of passing through each heat sink 28.

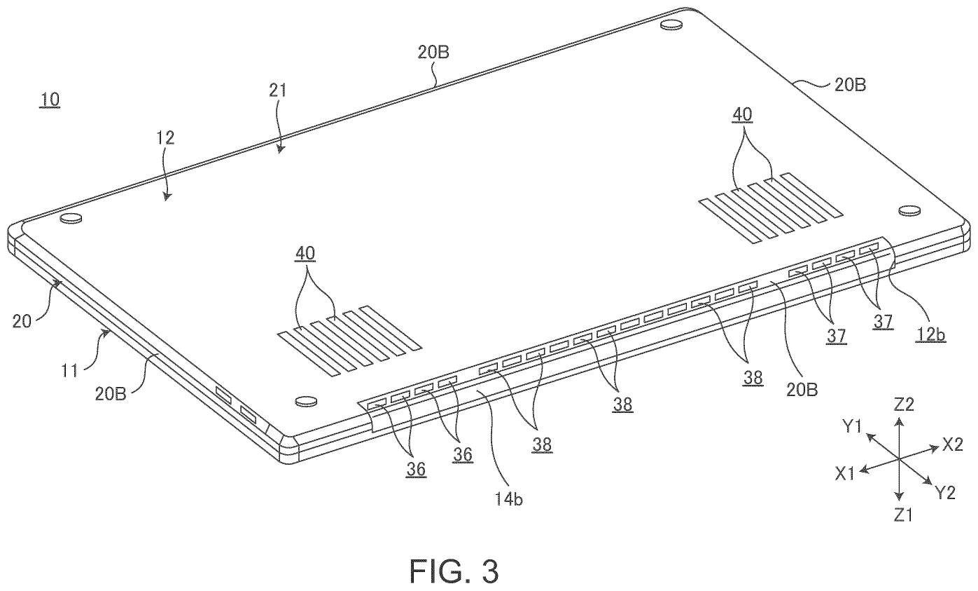

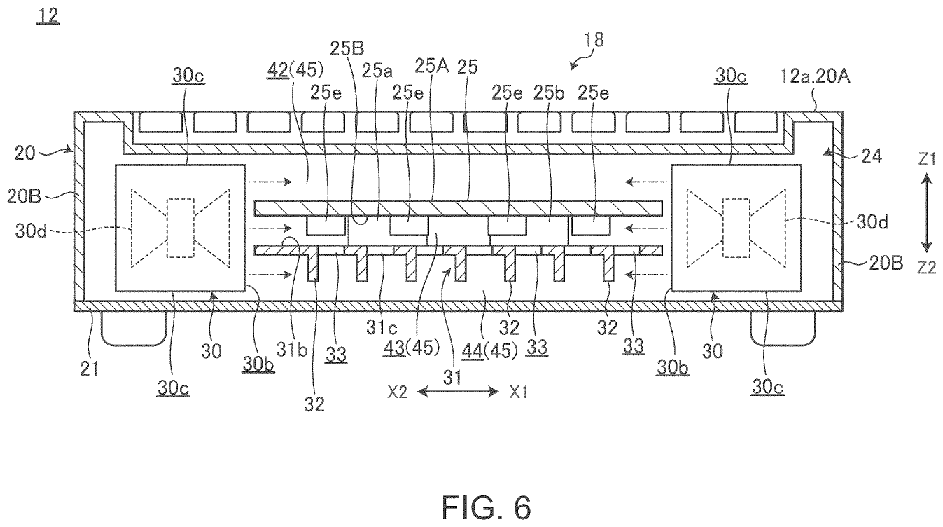

As illustrated in FIG. 2, the fans 30 are provided at positions close to the Y1 side of the left and right heat sinks 28. The fan 30 has the first outlet 30a and a second outlet 30b. The fan 30 has an intake port 30c on one or both of a top surface and a bottom surface. The fan 30 is a centrifugal fan that rotates an impeller 30d accommodated inside a housing via a motor (see FIG. 6). The fan 30 sucks in air from the intake port 30c and discharges the air from the outlets 30a and 30b. The intake port 30c is also capable of sucking in air from the outside of the chassis 12 through a bottom ventilation port 40 that is open to a bottom surface (cover material 21) of the chassis 12 (see FIGS. 3 and 5).

The first outlet 30a discharges air in the Y2 direction. The air sent from the first outlet 30a passes through the heat sink 28. The air that has passed through the heat sink 28 is discharged to the outside of the chassis 12 through ventilation ports 36 and 37 formed in the outer wall 20B of the chassis 12.

The second outlet 30b discharges air in the X1 direction or in the X2 direction. In the fan 30 disposed on the X1 side in FIG. 2, the second outlet 30b is open on the X2 side surface. In the fan 30 disposed on the X2 side in FIG. 2, the second outlet 30b is open on the X1 side surface. As a result, the second outlets 30b of the left and right fans 30 face each other with the portion 25C of the motherboard 25 and the metal plate 31 interposed therebetween.

It is preferable that the second outlet 30b is positioned in the Z direction so as to face side end surfaces of the motherboard 25 and the metal plate 31 (see FIG. 5). As a result, the second outlet 30b of each fan 30 is capable of discharging air toward top and bottom surfaces (surfaces 25A and 25B) of the motherboard 25 and top and bottom surfaces 31b and 31c of the metal plate 31. The air discharged from the second outlet 30b cools the CPU 25a, the GPU 25b, the memory module 25c, and the like while flowing along the surfaces 25A and 25B and the surfaces 31b and 31c. The air is further discharged to the outside of the chassis 12 through a third ventilation port 38 formed in the outer wall 20B of the chassis 12 while cooling the surfaces 31b and 31c of the metal plate 31 and the fins 32.

FIG. 3 is a perspective view of a rear portion of the electronic apparatus 10 as viewed from a bottom surface side.

As illustrated in FIG. 3, the chassis 12 has a first ventilation port 36, a second ventilation port 37, and the third ventilation port 38 on the outer wall 20B. The respective ventilation ports 36 to 38 are capable of being configured by, for example, a plurality of small window-like openings arranged along the longitudinal direction of the outer wall 20B.

The first ventilation port 36 is provided at a position close to an end part of the outer wall 20B on the X1 side. The first ventilation port 36 is close to and faces the heat sink 28 on the X1 side (see also FIG. 2). The second ventilation port 37 is provided at a position close to an end part of the outer wall 20B on the X2 side. The second ventilation port 37 is close to and faces the heat sink 28 on the X2 side. The third ventilation port 38 is provided between the first ventilation port 36 and the second ventilation port 37 in the X direction. The third ventilation port 38 is close to and faces the one edge portion 31a of the metal plate 31 and an edge portion on the Y2 side of the portion 25C of the motherboard 25 (see also FIG. 5).

Next, a specific configuration example of the metal plate 31 will be described.

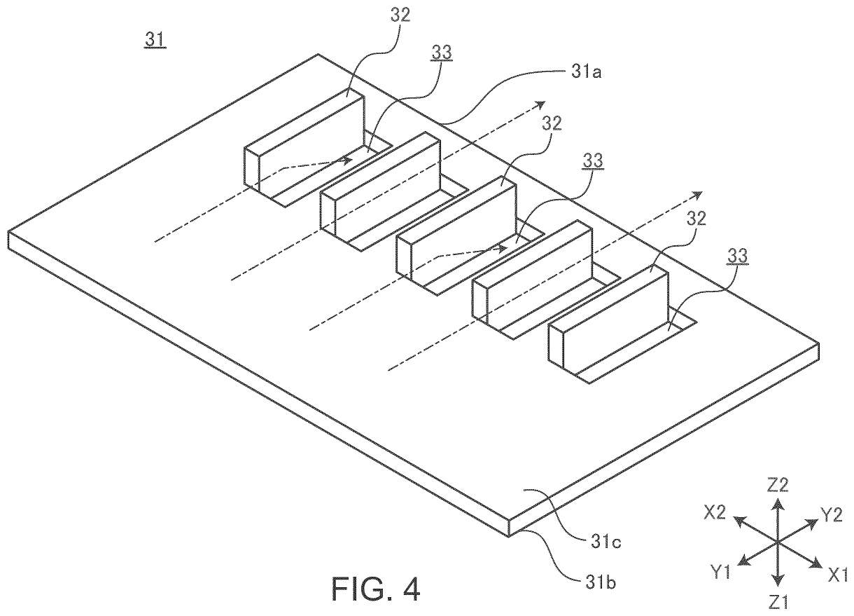

FIG. 4 is a schematic perspective view of the metal plate 31. FIG. 5 is a schematic cross-sectional side view of a rear edge portion of the chassis 12 and a peripheral portion thereof. FIG. 6 is a schematic cross-sectional rear view of the rear edge portion of the chassis 12 and the peripheral portion thereof. FIGS. 5 and 6 are enlarged views illustrating the fins 32, the hole parts 33, and the peripheral portions thereof of the metal plate 31.

As illustrated in FIGS. 2 to 6, the edge portion (one edge portion 31a) of the metal plate 31 on the Y2 side extends to a position close to the third ventilation port 38. As a result, the metal plate 31 covers the portion 25C of the motherboard 25 that extends to a position close to the third ventilation port 38. The metal plate 31 has the fins 32 and the hole parts 33 on the one edge portion 31a facing the third ventilation port 38.

The fins 32 are plate pieces that stand upright from the surface 31c of the metal plate 31 in the Z2 direction and that extend in the Y direction. The plurality of fins 32 is arranged in the X direction along the one edge portion 31a. As a result, a gap (air passage) extending in the Y direction is formed between the fins 32 and 32 adjacent to each other. Each fin 32 is capable of being configured as a cutout piece obtained by cutting out a part of the metal plate 31.

The hole part 33 is a through-hole that penetrates the metal plate 31 in a plate thickness direction (Z direction). The plurality of hole parts 33 is arranged in the X direction along the one edge portion 31a. Each hole part 33 is capable of being configured as a cutout hole formed in a portion where the fin 32 is cut out. In this case, each hole part 33 is disposed adjacent to each fin 32 in the X direction.

As described above, the edge portion on the Y2 side of the portion 25C of the motherboard 25 extends to a position close to the third ventilation port 38 (see FIGS. 2 and 5). The electronic apparatus 10 is, for example, a portable laptop PC. The chassis 12 needs to be made as small as possible, and an internal space thereof is narrow. Therefore, the motherboard 25 is extended to a position close to the outer wall 20B to ensure a mounting space for the mounted components. Due to this configuration, in one or more embodiments, the portion 25C of the motherboard 25 vertically overlaps the fins 32 and the hole parts 33. Therefore, an electronic component 25e may be mounted on the motherboard 25 at a position that vertically overlaps the fins 32 (see FIGS. 5 and 6). Examples of the electronic component 25e include power supply components and memories for the CPU 25a and the GPU 25b, and the like.

Therefore, it is preferable that the fins 32 stand upright in the Z2 direction from a surface 31c opposite to a surface (surface 31b) of the metal plate 31 facing the motherboard 25 (see FIGS. 5 and 6). In this case, it is possible to prevent the fins 32 from interfering with the motherboard 25 and the electronic components 25e. Due to this interference, it is also possible to prevent the electronic component 25e from causing a defect such as a short circuit. The fins 32 are capable of ensuring a sufficient standing height and increasing a surface area for heat exchange. Furthermore, by reducing a height in the Z direction between the motherboard 25 and the metal plate 31, it is possible to make the chassis 12 thinner. The standing height of the fins 32 from the surface 31c is capable of being, for example, about the same as or slightly higher than a thickness of the heat pipe 27 (see FIG. 5).

As described above, the metal plate 31 has the fins 32 and the hole parts 33 on the one edge portion 31a facing the third ventilation port 38. As a result, the air discharged from the second outlets 30b of the left and right fans 30 passes through the periphery of the fins 32 from the surfaces 25A and 25B of the motherboard 25 and the surfaces 31b and 31c of the metal plate 31 and is then discharged to the outside of the chassis 12 through the third ventilation port 38. In this case, a part of the air that has flowed through the space (flow path 44) between the surface 31c and the cover material 21 passes through the hole parts 33 and is then discharged to the third ventilation port 38 from the surface 31b side.

Specifically, in the electronic apparatus 10 of one or more embodiments, flow paths 42 to 44 of air flowing from the second outlet 30b to the third ventilation port 38 are formed in the chassis 12, and the fins 32 and the hole parts 33 are disposed on the flow path 42.

The flow path 42 closest to the Z1 side is a path that passes between the keyboard device 18 and the first surface 25A of the motherboard 25 and that leads to the third ventilation port 38. The intermediate flow path 43 is a path that passes between the second surface 25B of the motherboard 25 and the surface 31b of the metal plate 31 and that leads to the third ventilation port 38. The flow path 44 closest to the Z2 side is a path that passes between the surface 31c of the metal plate 31 and the cover material 21 and that leads to the third ventilation port 38. The flow path 44 communicates with the flow path 43 via the hole part 33. Arrows indicated by one-dot chain lines in FIGS. 2, 4, 5, and 6 schematically indicate a flow of air.

As illustrated in FIG. 2, a space (duct structure portion 45) for making a flow of air through the flow paths 42 to 44 smoother is capable of being formed inside the chassis 12. A range of the duct structure portion 45 is formed between the first surface 25A, the keyboard device 18, and the cover material 21 in the Z direction. A range of the duct structure portion 45 is formed between the left and right fans 30 and 30 and between the heat sinks 28 and 28 in the X direction. The third ventilation port 38 is located on the Y2 side of the duct structure portion 45.

An airtight wall 45a is preferably provided on a peripheral edge of the duct structure portion 45 except for the third ventilation port 38 side. The airtight wall 45a is, for example, a member in which sponge or rubber is formed in a band shape. The airtight wall 45a does not need to completely block the passage of air, but needs to regulate a direction in which air flows with a certain degree of ventilation resistance.

Next, the operation and the effects of the cooling module 24 in the electronic apparatus 10 will be described.

As illustrated in FIGS. 2 to 6, the electronic apparatus 10 includes the chassis 12 having the ventilation ports 36 to 38 in the outer wall 20B, and the cooling module 24. The chassis 12 mounts a substrate (motherboard 25) on which a heating element such as the CPU 25a and the GPU 25b is mounted. The cooling module 24 includes the heat sinks 28 disposed to face the ventilation ports 36 and 37, a heat transport device (heat pipe 27) that transports heat from the CPU 25a and the like to the heat sink 28, the fan 30 having the first outlet 30a capable of discharging air toward each heat sink 28, and the metal plate 31. The metal plate 31 is disposed between the fans 30 and 30 such that the one edge portion 31a faces the third ventilation port 38, and is capable of diffusing the heat from the CPU 25a and the like. The metal plate 31 has the plurality of fins 32 and the hole parts 33 arranged along the one edge portion 31a.

Therefore, in the electronic apparatus 10, the heat generated by the heating element such as the CPU 25a is transferred to the heat pipe 27 via the metal plate 31 and is efficiently transported to the heat sink 28. The heat transported to the heat sink 28 is smoothly discharged to the outside of the chassis 12 by the air flowing from the first outlet 30a of the fan 30 to the ventilation ports 36 and 37.

Furthermore, in the electronic apparatus 10, a part of the heat transferred from the CPU 25a and the like to the metal plate 31 and a part of the heat generated by the memory module 25c, the electronic component 25e, and the like are diffused by the metal plate 31. The heat diffused by the metal plate 31 is radiated to the flow paths 42 to 44 and is also conducted to the fins 32. The heat radiated to the flow paths 42 to 44 is smoothly discharged to the outside of the chassis 12 by the air flowing from the second outlet 30b to the third ventilation port 38.

In this case, since the air flowing through the flow path 44 cools the fins 32, the metal plate 31 is efficiently cooled, and thus the cooling efficiency of the CPU 25a and the like is improved. In addition, a part of the air flowing through the flow path 44 passes through the hole part 33 and flows out to the third ventilation port 38 via the flow path 43. As a result, the one edge portion 31a of the metal plate 31 is prevented from creating the ventilation resistance of the air flowing through the flow path 44. Therefore, an air volume of the fan 30 increases. In this manner, the cooling performance of the cooling module 24 is improved by the cooling effect of the metal plate 31 due to the fins 32 and the increase in the air volume of the fan 30 due to the hole parts 33.

In the cooling module 24, each fin 32 is capable of being formed as a cutout piece, and each hole part 33 is capable of being formed as a cutout hole formed in a portion where each fin 32 is cut out. In this case, the metal plate 31 is capable of reducing the ventilation resistance while ensuring a surface area for heat exchange with the air flowing through the flow paths 43 and 44. In particular, in the electronic apparatus 10, not only the metal plate 31 but also the motherboard 25 extends to just before the third ventilation port 38, and a path extending from the flow paths 42 to 44 to the third ventilation port 38 is narrowed. Therefore, the electronic apparatus 10 includes the hole parts 33 together with the fins 32 in the one edge portion 31a of the metal plate 31, and thus an increase in ventilation resistance is capable of being suppressed.

The fan 30 may be configured without the second outlet 30b. In this case, the third ventilation port 38 functions as an air intake port for the fan 30 to take in air outside the chassis 12 toward the intake port 30c. The outside air taken in from the third ventilation port 38 passes through the hole part 33 while cooling the fins 32 and is then introduced into the intake port 30c. In this case, the flow paths 43 and 44 communicate with each other through the hole part 33, so that the ventilation resistance is reduced, and the air volume of the fan 30 is improved.

The present invention is not limited to the above-described embodiments, and it goes without saying that the present invention can be freely modified without departing from the gist of the present invention.

For example, the fins 32 may be formed of a separate member instead of the cutout piece and fixed to the surface 31c. In this case, the hole part 33 need only be appropriately formed in the vicinity of the fin 32, and, for example, the hole part 33 may be configured as one long hole extending in the X direction.

### DESCRIPTION OF SYMBOLS

10 electronic apparatus
11 cover
12 chassis
24 cooling module
25 motherboard
25a CPU
25b GPU
25e electronic component
27 heat pipe
28 heat sink
30 fan
30a first outlet
30b second outlet
31 metal plate
31a one edge portion
36 first ventilation port
37 second ventilation port
38 third ventilation port
42 to 44 flow path

What is claimed is:

1. An electronic apparatus comprising:
a chassis including a first ventilation port, a second ventilation port, and a third ventilation port located between the first ventilation port and the second ventilation port;
a heating element mounted in the chassis; and
a cooling module mounted in the chassis and configured to cool the heating element,
wherein the cooling module includes
a pair of heat sinks, one of the heat sinks being disposed to face the first ventilation port and the other heat sink being disposed to face the second ventilation port,
a heat transport device configured to transport heat from the heating element to the heat sink,
a pair of fans each having a first outlet configured to discharge air toward the heat sink, one of the fans being disposed to face the one heat sink and the other fan being disposed to face the other heat sink, and
a metal plate disposed between the pair of fans such that one edge portion faces the third ventilation port and configured to diffuse the heat from the heating element, and
the metal plate includes
a plurality of fins standing upright from a surface of the metal plate and arranged along the one edge portion, and
a hole part penetrating the metal plate in a plate thickness direction.

2. The electronic apparatus according to claim 1,
wherein each of the pair of fans has a second outlet configured to discharge air toward the surface of the metal plate, and
at least one fin of the plurality of fins and the hole part are disposed on a flow path of air flowing from the second outlet to the third ventilation port.

3. The electronic apparatus according to claim 1,
wherein a plurality of the hole parts comprising the hole part is arranged along the one edge portion,
at least one fin of the plurality of fins is a cutout piece formed by cutting out a part of the metal plate, and
the hole part is a cutout hole formed in a portion where the at least one fin is cut out.

4. The electronic apparatus according to claim 1, further comprising:
a substrate on which the heating element is mounted,
wherein a part of the substrate vertically overlaps at least one fin of the plurality of fins and the hole part.

5. The electronic apparatus according to claim 4, further comprising:
an electronic component mounted on a portion of the substrate that vertically overlaps the fin,
wherein at least one fin of the plurality of fins stands upright from a surface opposite to a surface of the metal plate that faces the substrate.

6. A cooling module that is mounted in an electronic apparatus, the cooling module comprising:
a pair of heat sinks;
a heat transport device connected to the heat sinks;
a pair of fans each having a first outlet configured to discharge air toward the heat sink, one of the fans being disposed to face one of the heat sinks and the other being disposed to face the other of the heat sinks; and
a metal plate disposed between the pair of fans,
wherein the metal plate includes
a plurality of fins standing upright a surface of the metal plate and arranged along one edge portion of the metal plate, and
a hole part penetrating the metal plate in a plate thickness direction.

7. The cooling module according to claim 6,
wherein each of the pair of fans has a second outlet configured to discharge air toward the surface of the metal plate.

8. The cooling module according to claim 6,
wherein a plurality of the hole parts is arranged along the one edge portion,
at least one fin of the plurality of fins is a cutout piece formed by cutting out a part of the metal plate, and
the hole part is a cutout hole formed in a portion where the at least one fin is cut out.
